(19) United States
(12) Patent Application Publication
(10) Pub. No.: US 2015/0143914 A1
(43) Pub. Date: May 28, 2015

(54) PIEZOELECTRIC ACTUATOR MODULE AND MEMS SENSOR HAVING THE SAME

(71) Applicant: SAMSUNG ELECTRO-MECHANICS CO., LTD., Gyeonggi-Do (KR)

(72) Inventors: Seung Mo LIM, Gyeonggi-Do (KR); Yun Sung KANG, Gyeonggi-Do (KR); In Young KANG, Gyeonggi-Do (KR); Jeong Suong YANG, Gyeonggi-Do (KR); Jae Chang LEE, Gyeonggi-Do (KR)

(73) Assignee: SAMSUNG ELECTRO-MECHANICS CO., LTD., Gyeonggi-Do (KR)

(21) Appl. No.: 14/291,475

(22) Filed: May 30, 2014

(30) Foreign Application Priority Data
Nov. 27, 2013 (KR) 10-2013-0145520

(51) Int. Cl. H01L 41/083; G01H 11/08

(52) U.S. Cl. CPC H01L 41/083; G01H 11/08
USPC 73/658; 310/348

(57) ABSTRACT

Embodiments of the invention provide a piezoelectric actuator module, which includes a multilayer part comprising a multilayer piezoelectric material part and an electrode part connected to the multilayer piezoelectric material part, and a support layer coupled with the multilayer part. The piezoelectric actuator module further includes a support part displaceably supporting the support layer. The multilayer piezoelectric material part is poled in the same direction, and the multilayer part is configured to expand or contract when voltages in anti-phase are applied to the electrode part.

### CROSS REFERENCE TO RELATED APPLICATION

This application claims the benefit of and priority under 35 U.S.C. §119 to Korean Patent Application No. KR 10-2013-0145520, entitled “PIEZOELECTRIC ACTUATOR MODULE AND MEMS SENSOR HAVING THE SAME,” filed on Nov. 27, 2013, which is hereby incorporated by reference in its entirety into this application.

### BACKGROUND

1. Field of the Invention

The present invention relates to a piezoelectric actuator module and an MEMS sensor including the same.

2. Description of the Related Art

Micro electro mechanical systems (MEMS) are the technology of manufacturing very small devices, such as a very large scale integrated circuit, an inertial sensor, a pressure sensor, or an oscillator, as non-limiting examples, by processing silicon, crystal, or glass, as non-limiting examples. MEMS devices can be precise up to a micrometer (1/1,000,000 meter) or less and are manufactured by applying a semiconductor micro process technology of repeating deposition processes, or etching processes, as non-limiting examples, and thus may be massive-produced with a micro size at low cost.

Among those MEMS devices, a piezoelectric actuator operates in a manner that electric field is applied to a piezoelectric material so that the piezoelectric material contracts and expands. A vibration plate coupled with the piezoelectric material is deformed as the piezoelectric material contracts and expands.

Recently, piezoelectric actuators with the above-mentioned structure are implemented as multilayer piezoelectric actuator in which a plurality of piezoelectric materials is stacked on one another so as to improve displacement or vibration force.

Unfortunately, as described, for example, in U.S. Pat. No. 6,232,701, a piezoelectric actuator including a plurality of piezoelectric materials has multilayer piezoelectric materials, and thus the poling process of the piezoelectric materials is quite difficult. Therefore, there is a problem in that productivity is degraded.

### SUMMARY

Accordingly, embodiments of the invention have been made in an effort to provide a piezoelectric actuator module in which a multilayer part includes a multilayer piezoelectric material part poled in the same direction and an electrode part, and the multilayer piezoelectric materials together expand and contract when a signal in anti-phase is applied to the multilayer piezoelectric material part, such that a piezoelectric actuator can exhibit high performance by simply adjusting a signal applied.

Further, embodiments of the invention have been made in an effort to provide a piezoelectric actuator module that exhibits high performance by applying voltages in anti-phase to piezoelectric materials, so that driving voltage is doubled and thus displacement is doubled.

According to various embodiments of the invention, there is provided a multilayer part comprising a multilayer piezoelectric material part and an electrode part connected to the multilayer piezoelectric material part, and a support layer coupled with the multilayer part. The piezoelectric actuator module further includes a support part displaceably supporting the support layer. The multilayer piezoelectric material part is poled in the same direction, and the multilayer part is configured to expand or contract when voltages in anti-phase are applied to the electrode part.

According to an embodiment, the multilayer piezoelectric material part of the multilayer part includes a first piezoelectric material, and a second piezoelectric material. The first piezoelectric material is stacked on and is configured to expand or contract in the same direction with the first piezoelectric material. The electrode part is connected to the first and second piezoelectric materials.

According to an embodiment, the electrode part of the multilayer part includes a first electrode connected to the first piezoelectric material, and a second electrode connected to the second piezoelectric material. The electrode part of the multilayer part further includes a third electrode disposed between the first piezoelectric material and the second piezoelectric material.

According to an embodiment, with respect to a stacking direction in which the multilayer part is coupled with the support layer, the second electrode is formed under the multilayer part to be in contact with the support layer, the second piezoelectric material is formed on the second electrode, the third electrode is formed between the second piezoelectric material and the first piezoelectric material, the first piezoelectric material is formed on the third electrode, and the first electrode is formed on the first piezoelectric material.

According to an embodiment, the third electrode is a ground electrode.

According to an embodiment, the voltage applied to the first electrode and the voltage applied to the second electrode have a phase difference of 180 degrees.

According to another embodiment, there is provided a piezoelectric actuator module, which includes a multilayer part comprising a piezoelectric material and a multilayer electrode part connected to the piezoelectric material, a support layer coupled with the multilayer part, and a support part displaceably supporting the support layer. The multilayer part is configured to expand or contract when voltages in anti-phase are applied to the multilayer electrode part.

According to an embodiment, the electrode part of the multilayer part includes a first electrode connected to one end of the piezoelectric material, and a second electrode connected to the other end of the piezoelectric material.

According to an embodiment, with respect to a stacking direction in which the multilayer part is coupled with the support layer, the second electrode is formed under the multilayer part to be coupled with the support layer, the piezoelectric material is formed on the second electrode, and the first electrode is formed on the piezoelectric material.

According to an embodiment, the second electrode is a ground electrode.

According to an embodiment, the voltage applied to the first electrode and the voltage applied to the second electrode have a phase difference of 180 degrees.

According to another embodiment, there is provided a piezoelectric actuator module, which includes a multilayer part comprising a multilayer piezoelectric material part and an electrode part connected to the multilayer piezoelectric material part, a support layer coupled with the multilayer part, and a support part displaceably supporting the support layer. The multilayer piezoelectric material part is poled in the opposite directions, and the multilayer part is configured to expand or contract when voltages in anti-phase are applied to connected electrodes of the electrode part and to a non-connected electrode of the electrode part.

According to an embodiment, the multilayer piezoelectric material part of the multilayer part includes a first piezoelectric material, and a second piezoelectric material. The first piezoelectric material is stacked on, and is configured to expand or contract in the same direction with the first piezoelectric material. The electrode part is connected to the first and second piezoelectric materials.

According to an embodiment, the electrode part of the multilayer part includes a first electrode connected to the first piezoelectric material, a second electrode connected to the second piezoelectric material, and a third electrode disposed between the first piezoelectric material and the second piezoelectric material. An end of the first electrode is connected to an end of the second electrode.

According to an embodiment, with respect to a stacking direction in which the multilayer part is coupled with the support layer, the second electrode is formed under the multilayer part to be coupled with the support layer, the second piezoelectric material is formed on the second electrode, the third electrode is formed between the second piezoelectric material and the first piezoelectric material, the first piezoelectric material is formed on the third electrode, and the first electrode is formed on the first piezoelectric material.

According to an embodiment, the voltage applied to the first and second electrodes and the voltage applied to the third electrode have a phase difference of 180 degrees.

According to another embodiment, there is provided a MEMS sensor, which includes a flexible substrate comprising excitation means and sensing means, a mass body coupled with the flexible substrate, and a post supporting the flexible substrate. The excitation means includes a multilayer piezoelectric material part, the multilayer piezoelectric material part including a multilayer piezoelectric material part and an electrode part connected to the multilayer piezoelectric material part, the multilayer piezoelectric material part is poled in the same direction, and the multilayer part is configured to expand or contract when voltages in anti-phase are applied to the electrode part.

According to an embodiment, the multilayer piezoelectric material part of the multilayer part includes a first piezoelectric material, and a second piezoelectric material, which the first piezoelectric material is stacked on, and is configured to expand or contract in the same direction with the first piezoelectric material. The electrode part is connected to the first and second piezoelectric materials.

According to an embodiment, the electrode part of the multilayer part includes a first electrode connected to the first piezoelectric material, a second electrode connected to the second piezoelectric material, and a third electrode disposed between the first piezoelectric material and the second piezoelectric material.

According to an embodiment, the third electrode is a ground electrode, and the voltage applied to the first electrode and the voltage applied to the second electrode have a phase difference of 180 degrees.

Various objects, advantages and features of the invention will become apparent from the following description of embodiments with reference to the accompanying drawings.

### BRIEF DESCRIPTION OF DRAWINGS

These and other features, aspects, and advantages of the invention are better understood with regard to the following Detailed Description, appended Claims, and accompanying Figures. It is to be noted, however, that the Figures illustrate only various embodiments of the invention and are therefore not to be considered limiting of the invention's scope as it may include other effective embodiments as well.

FIG. 1 is a diagram schematically showing a piezoelectric actuator module according to a first embodiment of the invention.

FIGS. 2A and 2B are views showing the driving of the piezoelectric actuator module shown in FIG. 1 according to the first embodiment of the invention.

FIG. 3 is a diagram schematically showing a piezoelectric actuator module according to a second embodiment of the invention.

FIGS. 4A and 4B are views showing the driving of the piezoelectric actuator module shown in FIG. 3 according to the second embodiment of the invention.

FIG. 4C is a graph showing voltages applied to first and second electrodes of the piezoelectric actuator module shown in FIG. 3 according to the second embodiment of the invention.

FIG. 4D is a graph showing experimental data of feedback voltage according to the driving voltage of an embodiment of the invention.

FIG. 5 is a diagram schematically showing a piezoelectric actuator module according to a third embodiment of the invention.

FIGS. 6A and 6B are views showing the driving of the piezoelectric actuator module shown in FIG. 5 according to the third embodiment of the invention.

FIGS. 7A to 7L are cross-sectional views for illustrating a method of manufacturing the piezoelectric actuator module shown in FIG. 1 according to an embodiment of the invention.

FIG. 8 is a cross-sectional view showing an MEMS sensor including a piezoelectric actuator module according to an embodiment of the invention.

### DETAILED DESCRIPTION

Advantages and features of the present invention and methods of accomplishing the same will be apparent by referring to embodiments described below in detail in connection with the accompanying drawings. However, the present invention is not limited to the embodiments disclosed below and may be implemented in various different forms. The embodiments are provided only for completing the disclosure of the present invention and for fully representing the scope of the present invention to those skilled in the art.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. Like reference numerals refer to like elements throughout the specification.

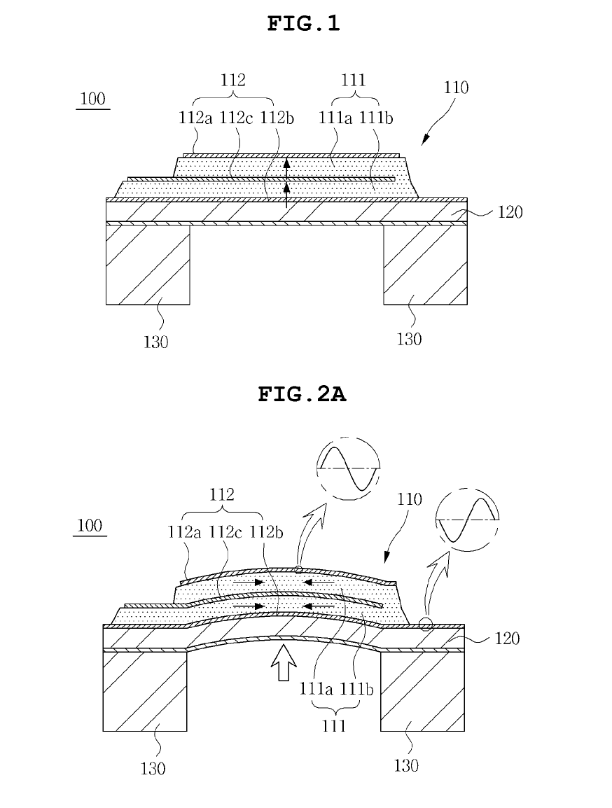

FIG. 1 is a diagram schematically showing a piezoelectric actuator module according to a first embodiment of the invention. As shown, the piezoelectric actuator module 100 includes a multilayer part 110, a support layer 120 and support parts 130.

According to an embodiment, the multilayer part 110 is disposed on the support layer 120, and the support layer 120 is displaceably supported by the support parts 130. The multilayer part 110 receives voltages having the phase difference and contracts or expands to thereby provide vibration force. To this end, the multilayer part 110 includes a multilayer piezoelectric material part 111 and an electrode part 112.

According to an embodiment, the multilayer piezoelectric material part 111 is poled in the same direction and expands or contracts in the same direction.

According to an embodiment, the piezoelectric material part 111 includes a first piezoelectric material 111a and a second piezoelectric material 111b, and the first piezoelectric material 111a are stacked above the second piezoelectric material 111b.

According to an embodiment, the first piezoelectric material 111a and the second piezoelectric material 111b are poled in the same direction as indicated by the arrows in FIG. 1. When an electric field is applied to the first piezoelectric material 111a and to the second piezoelectric material 111b, the first piezoelectric material 111a and the second piezoelectric material 111b contract or expand in the opposite directions. In the piezoelectric actuator module according to various embodiments of the invention, however, voltages having the phase difference of 180 degrees are applied to the first piezoelectric material 111a and to the second piezoelectric material 111b, such that the first piezoelectric material 111a and the second piezoelectric material 111b contract or expand in the same direction.

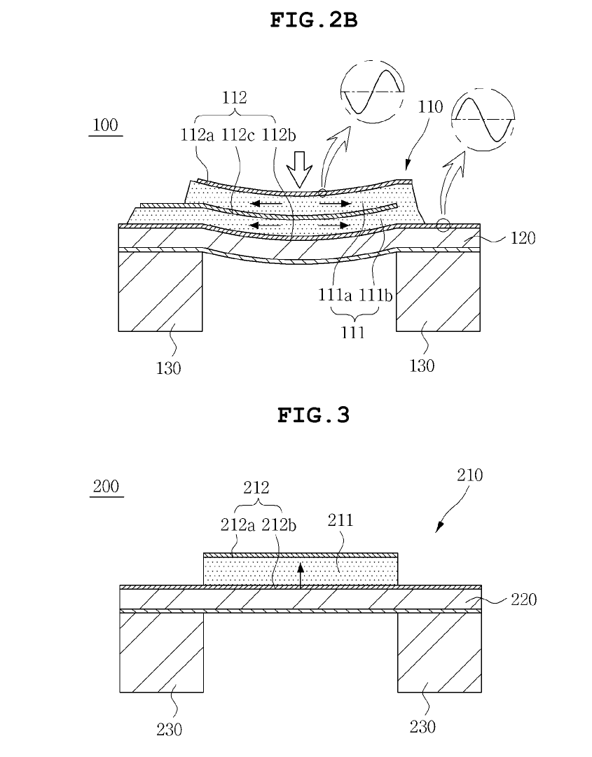

The technical implementation thereof will be described below with reference to FIGS. 2A and 2B.

According to an embodiment, the electrode part 112 includes a first electrode 112a, a second electrode 112b, and a third electrode 112c connected to the multilayer piezoelectric material part 111.

According to an embodiment, the first electrode 112a is connected to the first piezoelectric material 111a, the second electrode 112b is connected to the second piezoelectric material 111b, and the third electrode 112c is connected between the first piezoelectric material 111a and the second piezoelectric material 11b.

According to an embodiment, the third electrode 112c is used as a ground electrode.

Specifically, with respect to the direction in which the multilayer part 110 is coupled with the support layer 120, the second electrode 112b is formed under the multilayer part 110 to be coupled with the support layer 120, the second piezoelectric material 111b is formed on the second electrode 112b, the third electrode 112c is formed between the second piezoelectric material 111b and the first piezoelectric material 111a, the first piezoelectric material 111a is formed on the third electrode 112c, and the first electrode 112a is formed on the first piezoelectric material 111a.

Further, according to an embodiment, the first electrode 112a, the second electrode 112b, and the third electrode 112c are not connected to one another but are opened.

With this configuration, in the multilayer part 110, the first electrode 112a is the upper electrode, the second electrode 112b is the lower electrode, the third electrode 112c is the intermediate electrode, the first electrode 112a is located as the uppermost layer of the multilayer part 110, and the second electrode 112b is located as the lowermost layer of the multilayer part 110.

According to an embodiment, the support parts 130 are coupled with ends of the support layer so that the support layer 120 is displaceable.

Hereinafter, referring to FIGS. 2A and 2B, the principle of driving the piezoelectric actuator module shown in FIG. 1 and the behavior thereof will be described in detail.

FIGS. 2A and 2B are views showing the driving of the piezoelectric actuator module shown in FIG. 1 according to the first embodiment of the invention.

As shown in FIG. 2A, voltages in anti-phase, i.e., having the phase difference of 180 degrees are applied to the first electrode 112a and the second electrode 112b of the multilayer part 110 of the piezoelectric actuator module 100, respectively.

According to an embodiment, the first piezoelectric material 111a and the second piezoelectric material 111b connected to the first electrode 112a and the second electrode 112b, respectively, which are poled in the same direction to contract and expand in the opposite directions, expand or contract in the same direction by applying the voltages having the phase difference of the 180 degrees. FIG. 2A shows an exemplary embodiment thereof in which the first piezoelectric material 111a and the second piezoelectric material 111b contract in the same direction.

According to an embodiment, the ends of the support layer 120 are supported by the support parts 130, such that the centers of the multilayer part 110 and the support layer 120 are displaced upwardly as indicated by the arrow.

Then, as shown in FIG. 2B, when the voltages in the anti-phase each opposite to the respective voltages shown in FIG. 2A are applied to the first electrodes 112a and the second electrode 112b of the multilayer part 110 of the piezoelectric actuator module 100, respectively, the first piezoelectric material 111a and the second piezoelectric material 111b expand together as indicated by the arrows.

According to an embodiment, the centers of the multilayer part 110 and the support layer 120 are displaced downwardly as indicated by the arrow.

As described above, by repeating the operations shown in FIGS. 2A and 2B, the piezoelectric actuator module according to the first embodiment of the invention is implemented as a vibration actuator. The plurality of piezoelectric materials 111 poled in the same direction contracts and expands together by simply adjusting the phase differences of the applied voltages, such that a high performance piezoelectric actuator module are implemented.

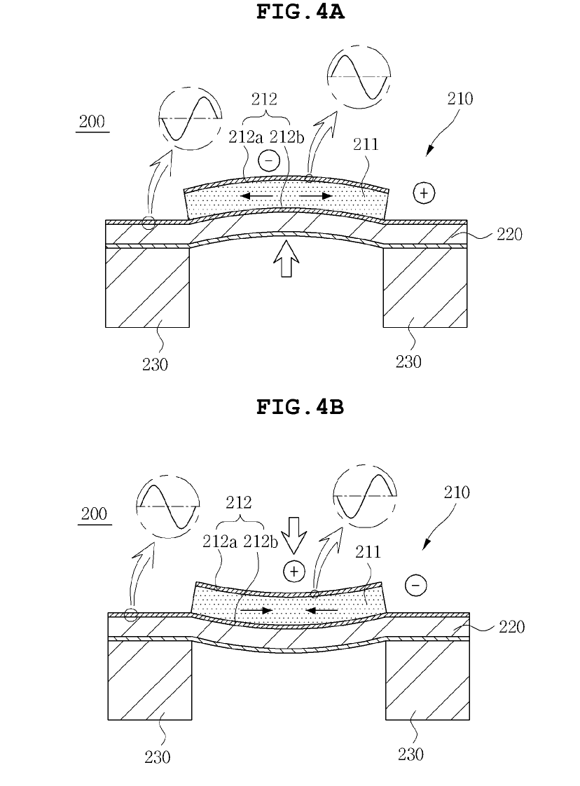

FIG. 3 is a diagram schematically showing a piezoelectric actuator module according to a second embodiment of the invention. As shown in FIG. 3, the piezoelectric actuator module 200 includes a multilayer part 210, a support layer 220 and support parts 230.

Specifically, the multilayer part 210 is disposed on the support layer 220, and the support layer 220 is displaceably supported by the support parts 230. The multilayer part 210 receives voltages out of phase and contracts or expands to thereby provide vibration force. To this end, the multilayer part 211 includes a piezoelectric material 211 and a multilayer electrode part 212.

Although the specific poling direction of the piezoelectric material 211 is indicated by the arrows in FIG. 3 for mere illustration, the poling direction is irrelevant to implementing a piezoelectric actuator module according to the second embodiment of the invention.

According to an embodiment, the multilayer electrode part 212 includes a first electrode 212a and a second electrode 212b connected to the piezoelectric material 211.

Further, the first electrode 212a is disposed on the piezoelectric material 211 as the upper electrode, and the second electrode 212b is disposed under the piezoelectric material 211 as the lower electrode.

According to an embodiment, the second electrode 212b is used as a ground electrode.

Specifically, with respect to the direction in which the multilayer part 210 is coupled with the support layer 220, the second electrode 212b is formed under the multilayer part 210 to be coupled with the support layer 220, the piezoelectric material 211 is formed on the second electrode 212b, and the first electrode 212a is formed on the piezoelectric material 211.

With this configuration, when voltages having the phase difference of 180 degrees are applied to the first electrode 212a and the second electrode 212b, the piezoelectric material 211 expand or contract.

Compared to when voltages with no phase difference are applied, displacement is doubled. This is because the driving voltage is doubled and thus the displacement is also doubled. That is, voltages having the phase difference of 180 degrees are applied to the piezoelectric material, such that the driving voltage is doubled and accordingly the displacement of the piezoelectric material is doubled.

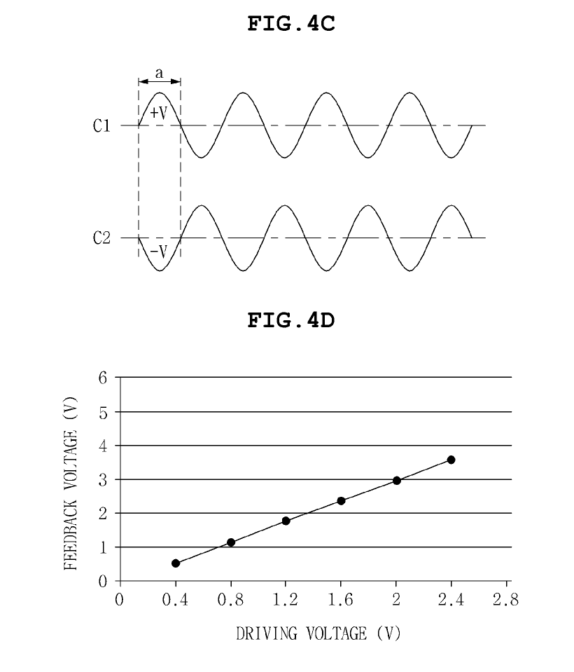

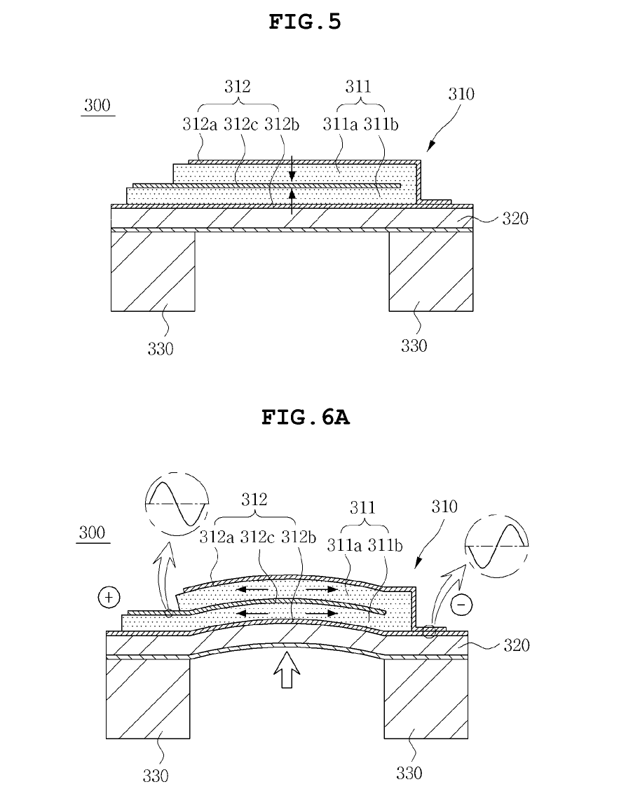

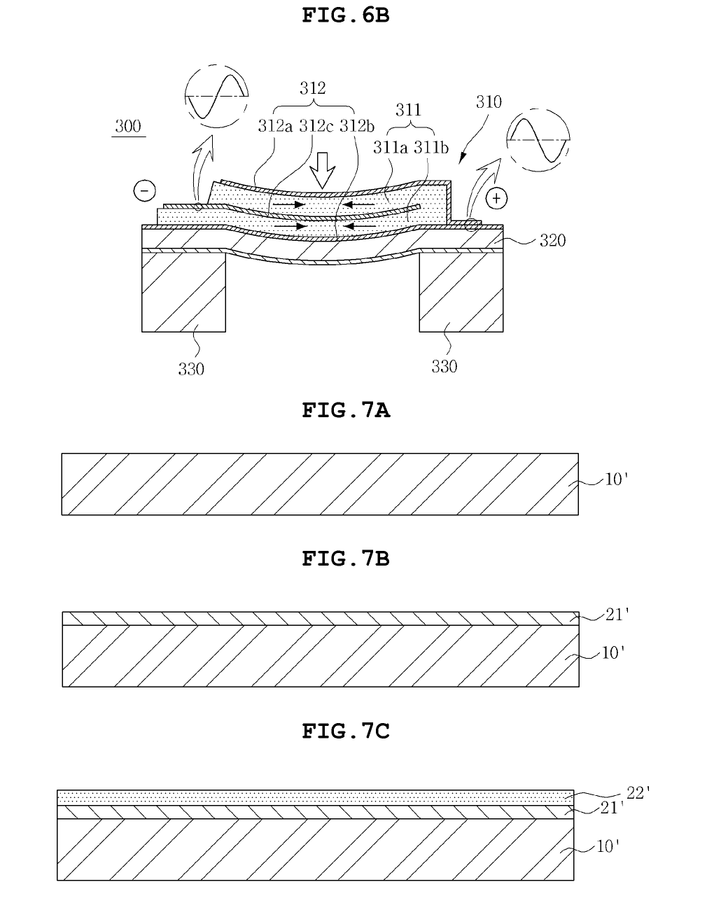

Hereinafter, referring to FIGS. 4A and 4B, the principle of driving the piezoelectric actuator module shown in FIG. 3 and the behavior thereof will be described in detail.

FIGS. 4A and 4B are views showing the driving of the piezoelectric actuator module shown in FIG. 3 according to the second embodiment of the invention.

As shown in FIG. 4A, voltages in anti-phase, i.e., having the phase difference of 180 degrees are applied to the first electrode 212a and the second electrode 212b of the multilayer part 210 of the piezoelectric actuator module 200, respectively.

When the voltages having the phase difference of 180 degrees are applied to the first electrode 212a and the second electrode 212b, respectively, the piezoelectric material 211 expands as indicated by the arrows, and the centers of the multilayer part 210 and the support layer 220 are displaced upwardly as indicated by the arrow with ends thereof supported by the support parts 230.

Then, as shown in FIG. 4B, when the voltages in anti-phase each opposite to the respective voltages shown in FIG. 4A are applied to the first electrodes 212a and the second electrode 212b of the multilayer part 210 of the piezoelectric actuator module 200, the piezoelectric material 211 contracts as indicated by the arrow.

Further, the centers of the multilayer part 210 and the support layer 220 are displaced downwardly as indicated by the arrow with the ends thereof supported by the support parts 230.

As described above, by repeating the operations shown in FIGS. 4A and 4B, the piezoelectric actuator module according to the second embodiment of the invention is implemented as a vibration actuator, which can provide stronger vibration force with longer displacement.

FIG. 4C is a graph showing voltages applied to first and second electrodes of the piezoelectric actuator module shown in FIG. 3 according to the second embodiment of the invention, and FIG. 4D is a graph showing experimental data of feedback voltage according to the driving voltage of an embodiment of the invention.

As shown, C1 is a graph of the voltage applied to the first electrode, which is the upper electrode, and C2 is a graph of the voltage applied to the second electrode, which is the lower electrode. The graphs C1 and C2 have the phase difference of 180 degrees, and the level of the voltage applied to the first electrode is +V and the level of the voltage applied to the second electrode is −V in region a.

Consequently, the voltage applied to the piezoelectric material in region a can be expressed as |+V|+|−V|=2V, and accordingly the displacement is at least doubled. This is proven by the experiment data of the feedback voltage according to driving voltage shown in FIG. 4D. That is, it can be seen that driving voltage is doubled from 0.4 to 0.8, and feedback voltage representing displacement is at least double from 0.5 V to 1.2 V.

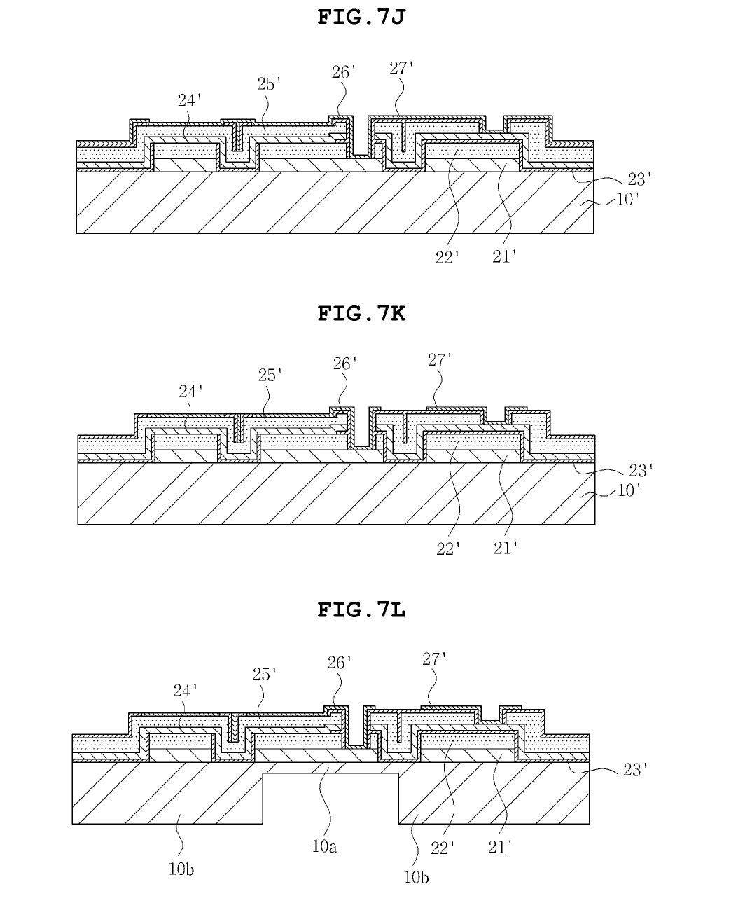

Further, since the change in the feedback voltage is equal to the change in displacement, it can be seen that the displacement is at least doubled from the experiment data shown in FIG. 7D.

With this configuration, the piezoelectric actuator module 200 according to the second embodiment of the invention has voltages having the phase difference of 180 degrees applied thereto, such that the driving voltage is doubled and the displacement of the piezoelectric material is double. Therefore, a high performance piezoelectric actuator module is implemented.

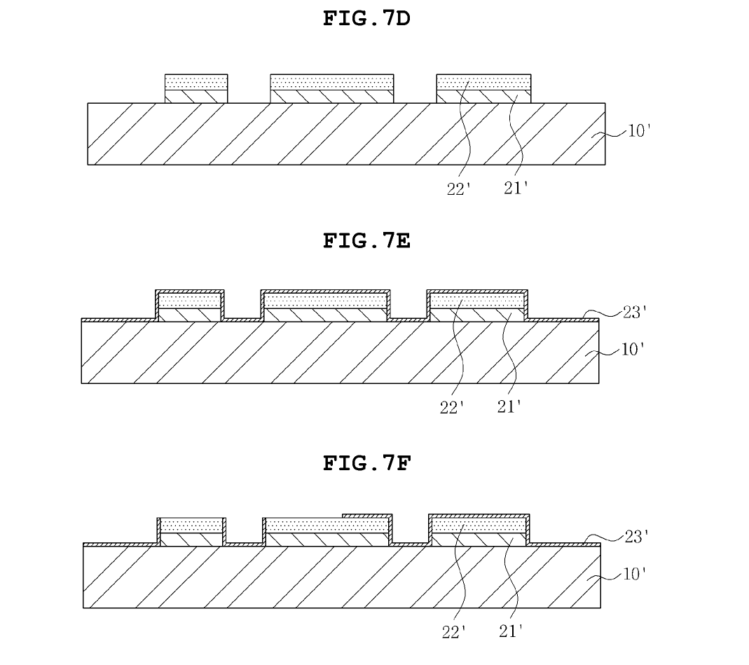

FIG. 5 is a diagram schematically showing a piezoelectric actuator module according to a third embodiment of the invention. As shown in FIG. 5, the piezoelectric actuator module 300 includes a multilayer part 310, a support layer 320 and support parts 330.

According to an embodiment, the multilayer part 310 is disposed on the support layer 320, and the support layer 320 is displaceably supported by the support parts 330.

According to an embodiment, the multilayer part 310 applies voltages having the phase difference of 180 degree to connected electrodes and a not-connected electrode so that piezoelectric materials contract or expand to thereby provide vibration force. To this end, the multilayer part 310 includes a multilayer piezoelectric material part 311 and an electrode part 312.

According to an embodiment, the multilayer piezoelectric material part 311 is poled in the opposite directions and expands or contracts in the same direction.

According to an embodiment, the multilayer piezoelectric material part 311 includes a first piezoelectric material 311a and a second piezoelectric material 311b, and the first piezoelectric material 311a is stacked above the second piezoelectric material 311b.

According to an embodiment, the first piezoelectric material 311a and the second piezoelectric material 311b are poled in the opposite directions as indicated by the arrows in FIG. 5.

In addition, voltages having the phase difference of 180 degrees are applied to the electrode parts 312a and 312b connected to the first piezoelectric material 311a and the second piezoelectric material 311b, respectively, and to the intermediate electrode part 312c, such that the first piezoelectric material 311a and the second piezoelectric material 311b contract or expand in the same direction.

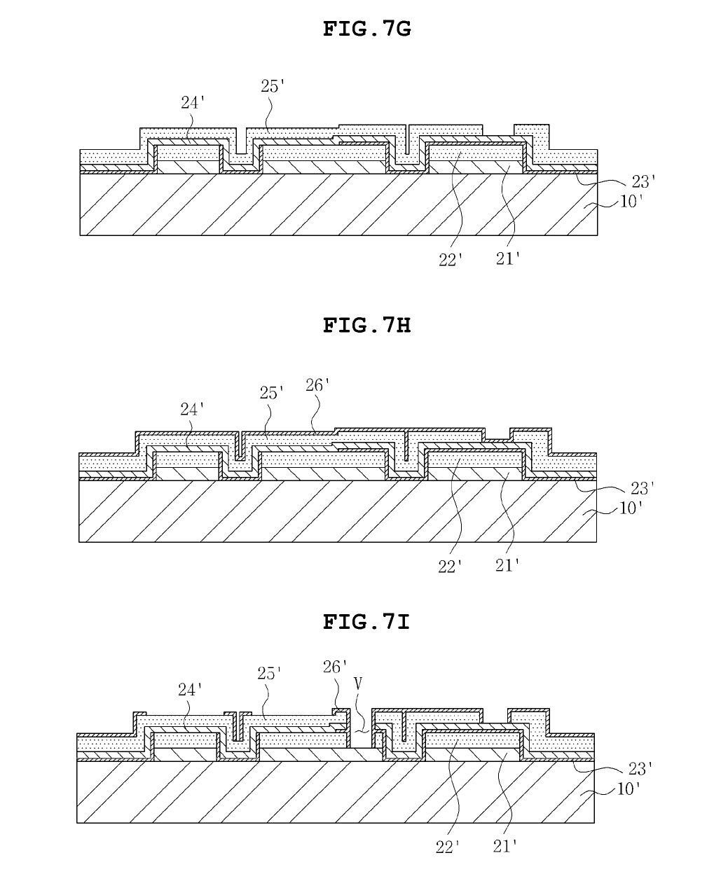

The technical implementation thereof will be described below with reference to FIGS. 6A and 6B.

According to an embodiment, the electrode part 312 includes a first electrode 312a, a second electrode 312b, and a third electrode 312c connected to the multilayer piezoelectric material part 311.

According to an embodiment, the first electrode 312a is connected to the first piezoelectric material 311a, the second electrode 312b is connected to the second piezoelectric material 311b, and the third electrode 312c is connected between the first piezoelectric material 311a and the second piezoelectric material 311b.

In addition, according to an embodiment, the end of the first electrode 312a is connected to the end of the second electrode 312b.

Further, the third electrode 312c is used as a ground electrode.

According to an embodiment, the, with respect to the direction in which the multilayer part 310 is coupled with the support layer 320, the second electrode 312b is formed under the multilayer part 310 to be coupled with the support layer 320, the second piezoelectric material 311b is formed on the second electrode 312b, the third electrode 312c is formed between the second piezoelectric material 311b and the first piezoelectric material 311a, the first piezoelectric material 311a is formed on the third electrode 312c, and the first electrode 312a is formed on the first piezoelectric material 311a.

With this configuration, in the multilayer part 310, the first electrode 312a is the upper electrode, the second electrode 312b is the lower electrode, the third electrode 312c is the intermediate electrode, the first electrode 312a is located as the uppermost layer of the multilayer part 310, and the second electrode 312b is located as the lowermost layer of the multilayer part 310.

According to an embodiment, the support parts 330 support the ends of the support layer 320, so that the support layer 320 is displaceable.

Hereinafter, referring to FIGS. 6A and 6B, the principle of driving the piezoelectric actuator module shown in FIG. 7 and the behavior thereof will be described in detail.

FIGS. 6A and 6B are views showing the driving of the piezoelectric actuator module shown in FIG. 5 according to the third embodiment of the invention.

As shown in FIG. 6A, a voltage is applied to the electrode to which the first electrode 312a and the second electrode 312b of the multilayer part 310 of the piezoelectric actuator module 300 are connected, and a voltage in anti-phase, i.e., having the phase difference of 180 degrees with the voltage is applied to the third electrode 312c. That is, the same voltage is applied to the first and second electrodes 312a and 312b, while the voltage having the phase difference of 180 degrees with the voltage is applied to the third electrode 312c.

Therefore, the first piezoelectric material 311a and the second piezoelectric material 311b expand or contract in the same direction. FIG. 6A shows an example in which the first piezoelectric material 311a and the second piezoelectric material 311b expand as indicated by the arrows. Further, the piezoelectric material part 311 and the electrode part 312 are coupled with the support layer 320 such that the centers of the multilayer part 310 and the support layer 320 are displaced upwardly.

Then, as shown in FIG. 6B, a voltage opposite to that shown in FIG. 6A is applied to the electrode to which the first electrode 312a and the second electrode 312b of the multilayer part 310 of the piezoelectric actuator module 300 are connected, and a voltage in anti-phase and opposite to that of the FIG. 6A is applied to the third electrode 312c. In this case, as indicated by the arrows, the first piezoelectric material 311a and the second piezoelectric material 311b contract together.

Further, the piezoelectric material part 311 and the electrode part 312 are coupled with the support layer 320, such that the centers of the multilayer part 310 and the support layer 320 are displaced downwardly.

With this configuration, the displacement of the multilayer piezoelectric material part is doubled, and because two layers of the first piezoelectric material and the second piezoelectric material are implemented, fourfold displacement is made. Accordingly, a high performance piezoelectric actuator module can be implemented.

FIGS. 7A to 7L are cross-sectional views for illustrating a method of manufacturing the piezoelectric actuator module shown in FIG. 1 according to an embodiment of the invention, in which the concept of the piezoelectric actuator module shown in FIG. 1 is applied.

As shown, FIG. 7A shows forming a wafer. Specifically, a wafer 10′ is prepared. According to an embodiment, the wafer 10′ has an oxide layer (not shown) formed on its outer circumference surface.

Then, FIG. 7B shows depositing a lower electrode. Specifically, a lower electrode 21′ is deposited on a surface of the wafer 10′.

Then, FIG. 7C shows depositing a second piezoelectric material. Specifically, the second piezoelectric material 22′ is deposited on a surface of the lower electrode 21′ deposited on the wafer 10′. The second piezoelectric material 22′ is deposited at the thickness of 1 μm.

Then, FIG. 7D shows patterning the lower electrode and the second piezoelectric material. Specifically, the lower electrode 21′ and the second piezoelectric material 22′ shown in FIG. 7C are patterned according to a specific design.

Then, FIG. 7E shows depositing SiO₂. Specifically, SiO₂ 23′ is deposited on the lower electrode 21′ patterned as shown in FIG. 7D, the second piezoelectric material 22′, and the wafer 10′. In addition, according to an embodiment, the SiO₂ 23′ is deposited at the thickness of 200 nm.

Then, FIG. 7F shows patterning SiO₂. Specifically, the SiO₂ 23′ deposited as shown in FIG. 7E is patterned in a predetermined pattern.

Then, FIG. 7G shows depositing an intermediate electrode and a first piezoelectric material. Specifically, the intermediate electrode 24′ is deposited on the SiO₂ 23′ and the second piezoelectric material 22′ pattern as shown in FIG. 7F, and the first piezoelectric material 25′ is deposited on a surface of the intermediate electrode 24′.

Then, FIG. 7H shows depositing SiO₂. Specifically, SiO₂ 26′ is deposited on the first piezoelectric material 25′ and the intermediate electrode 24′ deposited as shown in FIG. 7G. In addition, the SiO₂ 26′ is deposited at the thickness of 200 nm.

Then, FIG. 7I shows patterning SiO₂ and forming a via hole. Specifically, the SiO₂ 26′ deposited as shown in FIG. 7H is patterned in a predetermined pattern. Then, a via V is formed by performing etching, for example, on the SiO₂ 26′, the first piezoelectric material 25′, the intermediate electrode 24′, and the second piezoelectric material 22′ such that the lower electrode 21′ is exposed to the outside.

Then, FIG. 7J shows depositing an upper electrode. Specifically, the upper electrode 27′ is deposited on the SiO₂ 26, the first piezoelectric material 25′, and the lower electrode 21′ patterned as shown in FIG. 7I.

Then, FIG. 7K shows patterning the upper electrode. Specifically, the upper electrode 27′ deposited as shown in FIG. 7J is patterned in a predetermined pattern.

Then, FIG. 7L shows forming a support layer and support parts. Specifically, the wafer 10′ is etched so that a support layer 10a and a support parts 10b are formed.

By applying voltages to the first piezoelectric material 25′ and the second piezoelectric material 22′ thus configured to pole them in the same direction, to obtain the piezoelectric actuator module according to the first embodiment of the invention.

Then, signals having the phase difference of 180 degrees are applied to the lower electrode 21′ or the upper electrode 27′. In this case, as shown in FIGS. 5A and 5B, the first piezoelectric material 25′ and the second piezoelectric material 22′ contract and expand in the same direction, such that the center of the piezoelectric actuator module vertically vibrates.

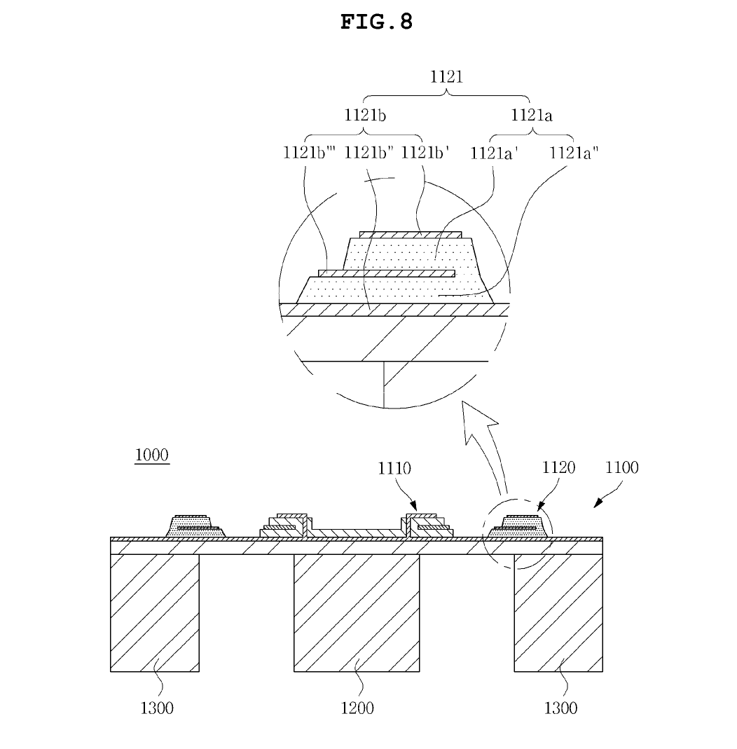

FIG. 8 is a cross-sectional view showing an MEMS sensor including a piezoelectric actuator module according to an embodiment of the invention. As shown in FIG. 8, an acceleration sensor 1000 includes a flexible substrate part 1100, a mass body 1200 and posts 1300.

According to an embodiment, the mass body 1200 is displaced by inertial force, Coriolis' force, external force, driving force and the like and is coupled with the flexible substrate part 1100.

According to an embodiment, the flexible substrate part 1100 has sensing means 1110 and excitation means 1120 are formed thereon. In addition, the flexible substrate part 1100 is coupled with the posts 1300 so that the mass body 1200 is displaceably supported by the posts 1300 in a floating state with the flexible substrate part 1100.

According to an embodiment, the excitation means 1120 on the flexible substrate part 1100 is implemented as the piezoelectric actuator module shown in FIG. 1. To this end, the excitation means 1120 includes a multilayer part 1121.

According to an embodiment, the sensing unit 1110 is one of a piezoelectric type, a piezoresistive type, a capacitive type and an optical type, for example, but is not particularly limited thereto.

According to an embodiment, the multilayer part 1121 receives an electric field from the outside and contracts or expands in order to provide vibration force, and includes a multilayer piezoelectric material part 1121a and an electrode part 1121b.

In addition, the multilayer piezoelectric material part 1121a is poled in the same direction, and one piezoelectric material among the adjacent piezoelectric materials expands or contracts in the opposite direction to another piezoelectric material.

According to an embodiment, the multilayer piezoelectric material part 1121a includes a first piezoelectric material 1121a′ and a second piezoelectric material 1121a″, and the first piezoelectric material 1121a′ is stacked above the second piezoelectric material 1121a″.

According to an embodiment, the electrode part 1121b includes a first electrode 1121b′, a second electrode 1121b″, and a third electrode 1121b′″.

Specifically, the first electrode 1121b′ is connected to the first piezoelectric material 1121a′, the second electrode 1121b″ is connected to the second piezoelectric material 1121a″, and the third electrode 1121b′″ is disposed between the first piezoelectric material 1121a′ and the second piezoelectric material 1121a″.

According to an embodiment, the third electrode 1121b′″ is used as a ground electrode.

According to an embodiment, with respect to the direction in which the multilayer part 1121 is coupled with a support part 1122, the second electrode 1121b″ is formed under the multilayer part 1121 to be coupled with the support part 1122, the second piezoelectric material 1121a″ is formed on the second electrode 1121b″, the third electrode 1121b′″ is formed between the second piezoelectric material 1121a″ and the first piezoelectric material 1121a′, the first piezoelectric material 1121a′ is formed on the third electrode 1121b′″, and the first electrode 1121b′ is formed on the first piezoelectric material 1121a′.

With this configuration, in the multilayer part 1121, the first electrode 1121b′ is the upper electrode, the second electrode 1121b″ is the lower electrode, the third electrode 1121b′″ is the intermediate electrode, the first electrode 1121b′ is located as the uppermost layer of the multilayer part 1121, and the second electrode 1121b″ is located as the lowermost layer of the multilayer part 1121.

In the angular velocity sensor thus configured and having the piezoelectric actuator module according to the present invention, when voltages having the phase difference of 180 degrees are applied to the first electrode 1121b′ and the second electrode 1121b″, the excitation means 1120 vibrates. Since the excitation means vibrates with high efficiency by the multilayer piezoelectric material part 1121a, the MEMS sensor senses more accurately.

Further, a MEMS sensor according to another embodiment of the invention is implemented as an MEMS sensor including the piezoelectric actuator modules according to the second and third embodiments of the invention shown in FIGS. 3 and 5, respectively.

As set forth above, according to various embodiments of the invention, signals in anti-phase are applied to a multilayer piezoelectric material part poled in the same direction so that multilayer piezoelectric materials contract and expand together, such that a piezoelectric actuator module can exhibit high performance by simply adjusting a signal applied, Further, a piezoelectric actuator module that exhibits high performance can be achieved by applying voltages in anti-phase to piezoelectric materials, so that driving voltage is doubled and thus displacement is doubled.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

Embodiments of the present invention may suitably comprise, consist or consist essentially of the elements disclosed and may be practiced in the absence of an element not disclosed. For example, it can be recognized by those skilled in the art that certain steps can be combined into a single step.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The singular forms “a,” “an,” and “the” include plural referents, unless the context clearly dictates otherwise.

As used herein and in the appended claims, the words “comprise,” “has,” and “include” and all grammatical variations thereof are each intended to have an open, non-limiting meaning that does not exclude additional elements or steps.

As used herein, the terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “according to an embodiment” herein do not necessarily all refer to the same embodiment.

Ranges may be expressed herein as from about one particular value, and/or to about another particular value. When such a range is expressed, it is to be understood that another embodiment is from the one particular value and/or to the other particular value, along with all combinations within said range.

Although the present invention has been described in detail, it should be understood that various changes, substitutions, and alterations can be made hereupon without departing from the principle and scope of the invention. Accordingly, the scope of the present invention should be determined by the following claims and their appropriate legal equivalents.

What is claimed is:

1. A piezoelectric actuator module, comprising:
a multilayer part comprising a multilayer piezoelectric material part and an electrode part connected to the multilayer piezoelectric material part;
a support layer coupled with the multilayer part; and
a support part displaceably supporting the support layer,
wherein the multilayer piezoelectric material part is poled in the same direction, and the multilayer part is configured to expand or contract when voltages in anti-phase are applied to the electrode part.

2. The piezoelectric actuator module according to claim 1, wherein the multilayer piezoelectric material part of the multilayer part comprises:
a first piezoelectric material; and
a second piezoelectric material, which the first piezoelectric material is stacked on, and is configured to expand or contract in the same direction with the first piezoelectric material, wherein the electrode part is connected to the first and second piezoelectric materials.

3. The piezoelectric actuator module according to claim 1, wherein the electrode part of the multilayer part comprises:
a first electrode connected to the first piezoelectric material;
a second electrode connected to the second piezoelectric material; and
a third electrode disposed between the first piezoelectric material and the second piezoelectric material.

4. The piezoelectric actuator module according to claim 3, wherein with respect to a stacking direction in which the multilayer part is coupled with the support layer, the second electrode is formed under the multilayer part to be in contact with the support layer, the second piezoelectric material is formed on the second electrode, the third electrode is formed between the second piezoelectric material and the first piezoelectric material, the first piezoelectric material is formed on the third electrode, and the first electrode is formed on the first piezoelectric material.

5. The piezoelectric actuator module according to claim 3, wherein the third electrode is a ground electrode.

6. The piezoelectric actuator module according to claim 3, wherein the voltage applied to the first electrode and the voltage applied to the second electrode have a phase difference of 180 degrees.

7. A piezoelectric actuator module, comprising:
a multilayer part comprising a piezoelectric material and a multilayer electrode part connected to the piezoelectric material;
a support layer coupled with the multilayer part; and
a support part displaceably supporting the support layer, wherein the multilayer part is configured to expand or contract when voltages in anti-phase are applied to the multilayer electrode part.

8. The piezoelectric actuator module according to claim 7, wherein the electrode part of the multilayer part comprises:
a first electrode connected to one end of the piezoelectric material; and
a second electrode connected to the other end of the piezoelectric material.

9. The piezoelectric actuator module according to claim 8, wherein with respect to a stacking direction in which the multilayer part is coupled with the support layer, the second electrode is formed under the multilayer part to be coupled with the support layer, the piezoelectric material is formed on the second electrode, and the first electrode is formed on the piezoelectric material.

10. The piezoelectric actuator module according to claim 8, wherein the second electrode is a ground electrode.

11. The piezoelectric actuator module according to claim 8, wherein the voltage applied to the first electrode and the voltage applied to the second electrode have a phase difference of 180 degrees.

12. A piezoelectric actuator module, comprising:
a multilayer part comprising a multilayer piezoelectric material part and an electrode part connected to the multilayer piezoelectric material part;
a support layer coupled with the multilayer part; and
a support part displaceably supporting the support layer,
wherein the multilayer piezoelectric material part is poled in the opposite directions, and the multilayer part is configured to expand or contract when voltages in anti-phase are applied to connected electrodes of the electrode part and to a non-connected electrode of the electrode part.

13. The piezoelectric actuator module according to claim 12, wherein the multilayer piezoelectric material part of the multilayer part comprises:
a first piezoelectric material; and
a second piezoelectric material, which the first piezoelectric material is stacked on, and is configured to expand or contract in the same direction with the first piezoelectric material,
wherein the electrode part is connected to the first and second piezoelectric materials.

14. The piezoelectric actuator module according to claim 12, wherein the electrode part of the multilayer part comprises:
a first electrode connected to the first piezoelectric material;
a second electrode connected to the second piezoelectric material; and
a third electrode disposed between the first piezoelectric material and the second piezoelectric material, wherein an end of the first electrode is connected to an end of the second electrode.

15. The piezoelectric actuator module according to claim 14, wherein with respect to a stacking direction in which the multilayer part is coupled with the support layer, the second electrode is formed under the multilayer part to be coupled with the support layer, the second piezoelectric material is formed on the second electrode, the third electrode is formed between the second piezoelectric material and the first piezoelectric material, the first piezoelectric material is formed on the third electrode, and the first electrode is formed on the first piezoelectric material.

16. The piezoelectric actuator module according to claim 15, wherein the voltage applied to the first and second electrodes and the voltage applied to the third electrode have a phase difference of 180 degrees.

17. An MEMS sensor, comprising:
a flexible substrate comprising excitation means and sensing means;
a mass body coupled with the flexible substrate; and
a post supporting the flexible substrate,
wherein the excitation means comprises a multilayer piezoelectric material part, the multilayer piezoelectric material part comprising a multilayer piezoelectric material part and an electrode part connected to the multilayer piezoelectric material part, the multilayer piezoelectric material part is poled in the same direction, and the multilayer part is configured to expand or contract when voltages in anti-phase are applied to the electrode part.

18. The MEMS sensor according to claim 17, wherein the multilayer piezoelectric material part of the multilayer part comprises:
a first piezoelectric material; and
a second piezoelectric material, which the first piezoelectric material is stacked on, and is configured to expand or contract in the same direction with the first piezoelectric material, wherein the electrode part is connected to the first and second piezoelectric materials.

19. The MEMS sensor according to claim 18, wherein the electrode part of the multilayer part comprises:
a first electrode connected to the first piezoelectric material;
a second electrode connected to the second piezoelectric material; and
a third electrode disposed between the first piezoelectric material and the second piezoelectric material.

20. The MEMS sensor according to claim 19, wherein the third electrode is a ground electrode, and the voltage applied to the first electrode and the voltage applied to the second electrode have a phase difference of 180 degrees.
